(19) United States
(12) Patent Application Publication
(10) Pub. No.: US 2024/0090587 A1
(43) Pub. Date: Mar. 21, 2024

(54) CAPSULE MONITORING SYSTEM FOR AEROSOL-GENERATING DEVICE

(71) Applicant: Altria Client Services LLC, Richmond, VA (US)

(72) Inventors: Zack W. BLACKMON, Richmond, VA (US); Thomas TRAN, Richmond, VA (US); Terry BACHE, Richmond, VA (US); Jarrett KEEN, Richmond, VA (US); Niall GALLAGHER, Richmond, VA (US); Yannick HOURMAND, Haslingfield (GB); Guillaume MICHEL, Cambridge (GB); Rangaraj S. SUNDAR, Midlothian, VA (US); Raymond W. LAU, Glen Allen, VA (US); Eric HAWES, Midlothian, VA (US)

(73) Assignee: Altria Client Services LLC, Richmond, VA (US)

(21) Appl. No.: 17/947,372

(22) Filed: Sep. 19, 2022

(51) Int. Cl. A24F 40/53; A24F 40/57; A24F 40/60; G01R 21/133; G01R 27/02

(52) U.S. Cl. CPC A24F 40/53; A24F 40/57; A24F 40/60; G01R 21/133; G01R 27/02

(57) ABSTRACT

A capsule monitoring system for an aerosol-generating device includes at least one processor and a memory. The memory is coupled to the at least one processor and storing instructions. The at least one processor is configured to execute the instructions to cause the capsule monitoring system to detect a mechanism detection switch of the aerosol-generating device being actuated, apply a first power to a first contact point of the aerosol-generating device, determine a first resistance between the first contact point and a second contact point, determine whether the first resistance is within a resistance operation range, and in response to the first resistance being within of the resistance operation range, display a capsule accepted indicator. The first contact point is configured to contact a heater. The second contact point is configured to contact the heater.

### TECHNICAL FIELD

At least some example embodiments relate to aerosol-generating devices and more particularly, but without limitation, to capsule monitoring systems for aerosol-generating devices.

### BACKGROUND

Some electronic devices are configured to heat a plant material to a temperature that is sufficient to release constituents of the plant material while keeping the temperature below a combustion point of the plant material so as to avoid any substantial pyrolysis of the plant material. Such devices may be referred to as aerosol-generating devices (e.g., heat-not-burn aerosol-generating devices), and the plant material heated may be tobacco and/or cannabis. In some instances, the plant material may be introduced directly into a heating chamber of an aerosol generating device. In other instances, the plant material may be pre packaged in individual containers to facilitate insertion and removal from an aerosol-generating device.

### BRIEF SUMMARY

Systems, apparatuses, and methods for control systems for aerosol-generating devices are set forth in the appended claims. Illustrative embodiments are also provided to enable a person skilled in the art to make and use the claimed subject matter.

At least one example embodiment relates to a capsule monitoring system for an aerosol-generating device. The capsule monitoring system comprises at least one processor and a memory coupled to the at least one processor and storing instructions. The at least one processor is configured to execute the instructions to cause the capsule monitoring system to detect actuation of a mechanism detection switch of the aerosol-generating device, apply a first power to a first contact point of the aerosol-generating device, determine a first resistance between the first contact point and a second contact point, determine whether the first resistance is within a resistance operation range, and display a capsule accepted indicator in response to the first resistance being within of the resistance operation range. The first contact point and the second contact point are configured to contact a heater.

In at least one example embodiment, the at least one processor is configured to execute the instructions to cause the capsule monitoring system to start a capsule monitor timer. The capsule monitor timer is configured to measure a capsule monitor time and to reset the capsule monitor timer in response to actuation of the mechanism detection switch of the aerosol-generating device.

In at least one example embodiment, the at least one processor is configured to execute the instructions to cause the capsule monitoring system to increase the first power until the first power exceeds a first power threshold.

In at least one example embodiment, the at least one processor is configured to execute the instructions to cause the capsule monitoring system to monitor the first power against the first power threshold, monitor the capsule monitor time against a time threshold, determine whether the first resistance is within a resistance range in response to the first power not exceeding the first power threshold and the capsule monitor time not exceeding the time threshold, and cease applying the first power to the first contact point of the aerosol-generating device in response to the first resistance not being within the resistance range.

In at least one example embodiment, a lower bound of the resistance range is about half of a minimum heater operation resistance.

In at least one example embodiment, the minimum heater operation resistance is about 2002 milliohms.

In at least one example embodiment, the at least one processor is configured to execute the instructions to cause the capsule monitoring system to display a fault indicator.

In at least one example embodiment, an upper bound of the resistance range is about 3327 milliohms.

In at least one example embodiment, the time threshold is about 217 milliseconds.

In at least one example embodiment, the at least one processor is configured to execute the instructions to cause the capsule monitoring system to monitor the first power against the first power threshold, monitor the capsule monitor time against a time threshold, determine whether the first resistance is within a resistance range in response to the first power not exceeding the first power threshold and the capsule monitor time not exceeding the time threshold, and increase the first power applied to the first contact point of the aerosol-generating device in response to the first resistance being within the resistance range.

In at least one example embodiment, the at least one processor is configured to execute the instructions to cause the capsule monitoring system to monitor the first power against the first power threshold, monitor the capsule monitor time against a time threshold, and cease applying the first power to the first contact point of the aerosol-generating device in response to the first power not exceeding the first power threshold and the capsule monitor time exceeding the time threshold.

In at least one example embodiment, the at least one processor is configured to execute the instructions to cause the capsule monitoring system to return the aerosol-generating device to normal operation.

In at least one example embodiment, the at least one processor is configured to execute the instructions to cause the capsule monitoring system to monitor the first power against the first power threshold, monitor the first resistance against a maximum heater resistance in response to the first resistance not being within the resistance operation range and the first power exceeding the first power threshold, and display a fault indicator in response to the first resistance not exceeding the maximum heater resistance.

In at least one example embodiment, the maximum heater resistance is about 3327 milliohms.

In at least one example embodiment, the at least one processor is configured to execute the instructions to cause the capsule monitoring system to monitor the first power against the first power threshold, monitor the first resistance against a maximum heater resistance in response to the first resistance not being within the resistance operation range and the first power exceeding the first power threshold, and return the aerosol-generating device to normal operation in response to the first resistance exceeding the maximum heater resistance.

In at least one example embodiment, the first power threshold is about 2 watts.

In at least one example embodiment, the at least one processor is configured to execute the instructions to cause the capsule monitoring system to monitor the first power against the first power threshold, and cease applying the first power to the first contact point in response to the first power exceeding the first power threshold.

In at least one example embodiment, the at least one processor is configured to execute the instructions to cause the capsule monitoring system to, store the first resistance in the memory of the capsule monitoring system after determining the first resistance is within the resistance operation range, detect start of a session of the aerosol-generating device, apply a preheat power to the first contact point of the aerosol-generating device, determine a preheat resistance between the first contact point and the second contact point, determine whether the preheat resistance is within a resistance tolerance range, and return the aerosol-generating device to a preheat operation of the session in response to the preheat resistance being within the resistance tolerance range. The resistance tolerance range is based on the first resistance stored in the memory of the aerosol-generating device

In at least one example embodiment, the at least one processor is configured to execute the instructions to cause the capsule monitoring system to increase the preheat power until the preheat power exceeds a preheat power threshold.

In at least one example embodiment, the at least one processor is configured to execute the instructions to cause the capsule monitoring system to monitor the preheat power against the preheat power threshold, determine whether the preheat resistance is within a resistance range in response the preheat power not exceeding the preheat power threshold, and cease applying the preheat power to the first contact point of the aerosol-generating device in response to the preheat resistance not being within the resistance range.

In at least one example embodiment, the at least one processor is configured to execute the instructions to cause the capsule monitoring system to monitor the preheat power against the preheat power threshold, determine whether the preheat resistance is within a resistance range in response the preheat power not exceeding the preheat power threshold, and increase the preheat power applied to the first contact point of the aerosol-generating device in response to the preheat resistance being within the resistance range.

In at least one example embodiment, the at least one processor is configured to execute the instructions to cause the capsule monitoring system to monitor the preheat power relative to the preheat power threshold, and cease applying the preheat power to the first contact point of the aerosol-generating device in response to the preheat resistance not being within the resistance tolerance range and the preheat power exceeding the preheat power threshold.

In at least one example embodiment, the preheat power threshold is about 2 watts.

In at least one example embodiment, a lower bound of the resistance tolerance range is about 15 milliohms lower than the first resistance stored in the memory of the aerosol-generating device and an upper bound of the resistance tolerance range is about 15 milliohms greater than the first resistance stored in the memory of the aerosol-generating device.

In at least one example embodiment, a lower bound of the resistance tolerance range is about 30 milliohms lower than the first resistance stored in the memory of the aerosol-generating device and an upper bound of the resistance tolerance range is about 30 milliohms greater than the first resistance stored in the memory of the aerosol-generating device.

In at least one example embodiment, the mechanism detection switch is configured to be actuated when a closure mechanism of the aerosol-generating device is closed.

In at least one example embodiment, the closure mechanism is configured to secure a capsule within the aerosol-generating device.

In at least one example embodiment, the capsule monitoring system further comprises a voltage measurement circuit configured to measure a voltage between the first contact point and the second contact point.

In at least one example embodiment, the capsule monitoring system further comprises a current measurement circuit configured to measure a current at one of the first contact point and the second contact point.

In at least one example embodiment, the at least one processor is configured to execute the instructions to cause the capsule monitoring system to initiate a preheat operation of the aerosol-generating device after at least one of determining the first resistance being within the resistance operation range or displaying the capsule accepted indicator.

At least one example embodiment relates to a capsule monitoring system for an aerosol-generating device comprising at least one processor and a memory coupled to the at least one processor and storing instructions. The at least one processor is configured to execute the instructions to cause the capsule monitoring system to detect start of a session of the aerosol-generating device, apply a preheat power to a first contact point of the aerosol-generating device, determine a preheat resistance between the first contact point and a second contact point, determine whether the preheat resistance is within a resistance tolerance range, and continue a preheat operation of the session in response to the preheat resistance being within the resistance tolerance range. The resistance tolerance range is based on a first resistance stored in the memory of the aerosol-generating device.

One or more example embodiments provide a method of operating a capsule monitoring system for an aerosol-generating device, the method comprising: detecting actuation of a mechanism detection switch of the aerosol-generating device; applying a first power to a first contact point of the aerosol-generating device; determining a first resistance between the first contact point and a second contact point; determining whether the first resistance is within a resistance operation range, and in response to the first resistance being within of the resistance operation range, displaying a capsule accepted indicator. The first contact point and the second contact point are configured to contact a heater.

One or more example embodiments provide a non-transitory computer-readable storage medium storing computer-readable instructions that, when executed by a controller at capsule monitoring system for an aerosol-generating device, cause the controller to perform a method of operating the capsule monitoring system for the aerosol-generating device, the method comprising: detecting actuation of a mechanism detection switch of the aerosol-generating device; applying a first power to a first contact point of the aerosol-generating device; determining a first resistance between the first contact point and a second contact point; determining whether the first resistance is within a resistance operation range, and in response to the first resistance being within of the resistance operation range, displaying a capsule accepted indicator. The first contact point and the second contact point are configured to contact a heater.

One or more example embodiments provide a method of operating a capsule monitoring system for an aerosol-generating device, the method comprising: detecting start of a session of the aerosol-generating device; applying a preheat power to a first contact point of the aerosol-generating device; determining a preheat resistance between the first contact point and a second contact point; determining whether the preheat resistance is within a resistance tolerance range; and continuing a preheat operation of the session in response to the preheat resistance being within the resistance tolerance range. The resistance tolerance range is based on a first resistance stored in the memory of the aerosol-generating device.

One or more example embodiments provide a non-transitory computer-readable storage medium storing computer-readable instructions that, when executed by a controller at capsule monitoring system for an aerosol-generating device, cause the controller to perform a method of operating the capsule monitoring system for the aerosol-generating device, the method comprising: detecting start of a session of the aerosol-generating device; applying a preheat power to a first contact point of the aerosol-generating device; determining a preheat resistance between the first contact point and a second contact point; determining whether the preheat resistance is within a resistance tolerance range; and continuing a preheat operation of the session in response to the preheat resistance being within the resistance tolerance range. The resistance tolerance range is based on a first resistance stored in the memory of the aerosol-generating device.

### BRIEF DESCRIPTION OF THE DRAWINGS

The various features and advantages of the non-limiting embodiments herein may become more apparent upon review of the detailed description in conjunction with the accompanying drawings. The accompanying drawings are merely provided for illustrative purposes and should not be interpreted to limit the scope of the claims. The accompanying drawings are not to be considered as drawn to scale unless explicitly noted. For purposes of clarity, various dimensions of the drawings may have been exaggerated.

FIG. 1 is a top right, front perspective view of a device in accordance with at least one example embodiment.

FIG. 2A is a top right, front perspective view of the device of FIG. 1, where the lid is opened and where the device includes a capsule.

FIG. 2B is a bottom right, front perspective view of the device of FIG. 1.

FIG. 2C is a bottom view of the device of FIG. 1.

FIG. 3 is a block diagram of a capsule monitoring system of the device of FIG. 1 in accordance with at least one example embodiment.

FIG. 4 is a block diagram of heating systems of the device of FIG. 1 and the capsule of FIG. 2 in accordance with at least one example embodiment.

FIG. 5 is a flow chart illustrating a method of operating the capsule monitoring system of FIG. 3 in accordance with at least one example embodiment.

FIG. 6 is a flow chart illustrating a method of operating the capsule monitoring system of FIG. 3 in accordance with at least one example embodiment.

FIG. 7 is a flow chart illustrating another method of operating the capsule monitoring system of FIG. 3 in accordance with at least one example embodiment.

FIG. 8 is a flow chart illustrating a method of operating the capsule monitoring system of FIG. 3.

### DESCRIPTION OF EXAMPLE EMBODIMENTS

Some detailed example embodiments are disclosed herein. However, specific structural and functional details disclosed herein are merely representative for purposes of describing example embodiments. Example embodiments may, however, be embodied in many alternate forms and should not be construed as limited to only the example embodiments set forth herein.

Accordingly, while example embodiments are capable of various modifications and alternative forms, example embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It should be understood that when an element or layer is referred to as being “on,” “connected to,” “coupled to,” or “covering” another element or layer, it may be directly on, connected to, coupled to, or covering the other element or layer or intervening elements or layers may be present. In contrast, when an element is referred to as being “directly on,” “directly connected to,” or “directly coupled to” another element or layer, there are no intervening elements or layers present. As used herein, the term “and/or” includes any and all combinations of one or more of the associated listed items.

It should be understood that, although the terms first, second, third, etc. may be used herein to describe various elements, regions, layers and/or sections, these elements, regions, layers, and/or sections should not be limited by these terms. These terms are only used to distinguish one element, region, layer, or section from another region, layer, or section. Thus, a first element, component, region, layer, or section discussed below could be termed a second element, region, layer, or section without departing from the teachings of example embodiments.

Spatially relative terms (e.g., “beneath,” “below,” “lower,” “above,” “upper,” and the like) may be used herein for ease of description to describe one element or feature's relationship to another element(s) or feature(s) as illustrated in the figures. It should be understood that the spatially relative terms are intended to encompass different orientations of the device in use or operation in addition to the orientation depicted in the figures. For example, if the device in the figures is turned over, elements described as “below”, or “beneath” other elements or features would then be oriented “above” the other elements or features. Thus, the term “below” may encompass both an orientation of above and below. The device may be otherwise oriented (rotated 90 degrees or at other orientations) and the spatially relative descriptors used herein interpreted accordingly.

The terminology used herein is for the purpose of describing various example embodiments only and is not intended to be limiting of example embodiments. As used herein, the singular forms “a,” “an,” and “the” are intended to include the plural forms as well, unless the context clearly indicates otherwise. It will be further understood that the terms “includes,” “including,” “comprises,” and/or “comprising,” specify the presence of stated features, integers, steps, operations, and/or elements, but do not preclude the presence or addition of one or more other features, integers, steps, operations, elements, and/or groups thereof.

When the terms “about” or “substantially” are used in this specification in connection with a numerical value, it is intended that the associated numerical value includes a manufacturing or operational tolerance (e.g., ±10%) around the stated numerical value. Moreover, when the terms “generally” or “substantially” are used in connection with geometric shapes, it is intended that precision of the geometric shape is not required but that latitude for the shape is within the scope of the disclosure. Furthermore, regardless of whether numerical values or shapes are modified as “about,” “generally,” or “substantially,” it will be understood that these values and shapes should be construed as including a manufacturing or operational tolerance (e.g., ±10%) around the stated numerical values or shapes.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

As used herein, “coupled” includes both removably coupled and permanently coupled. For example, when an elastic layer and a support layer are removably coupled to one another, the elastic layer and the support layer can be separated upon the application of sufficient force.

Hardware may be implemented using processing or control circuitry such as, but not limited to, one or more processors, one or more Central Processing Units (CPUs), one or more microcontrollers, one or more arithmetic logic units (ALUs), one or more digital signal processors (DSPs), one or more microcomputers, one or more field programmable gate arrays (FPGAs), one or more System-on-Chips (SoCs), one or more programmable logic units (PLUs), one or more microprocessors, one or more Application Specific Integrated Circuits (ASICs), or any other device or devices capable of responding to and executing instructions in a defined manner.

One or more example embodiments may be described herein, in at least some instances, as being performed by a capsule monitoring system of an aerosol-generating device including at least one processor and a memory storing computer-executable instructions, wherein the at least one processor is configured to execute the computer-readable instructions to cause the capsule monitoring system to perform operations of one or more example embodiments. Additionally, the processor, memory and example algorithms, encoded as computer program code, may serve as means for providing or causing performance of operations discussed herein.

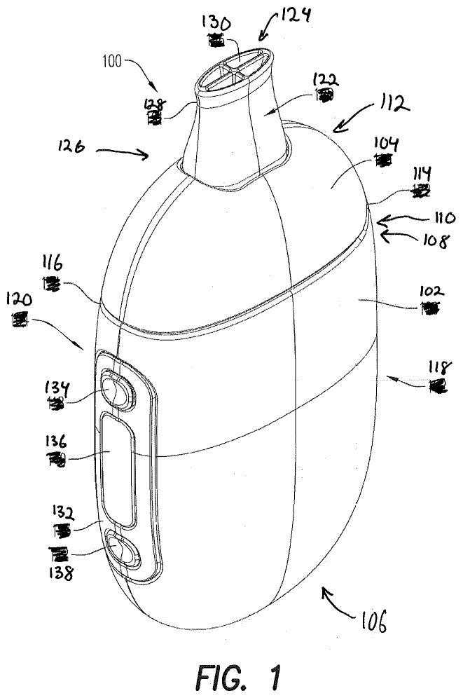

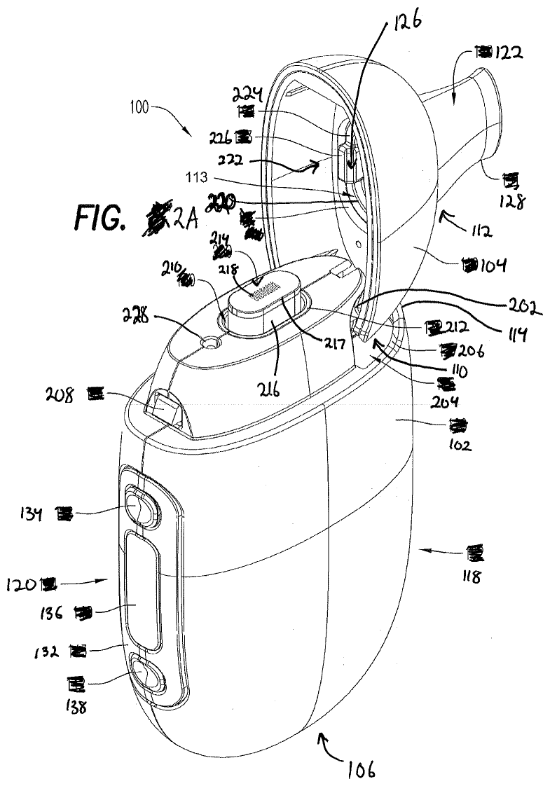

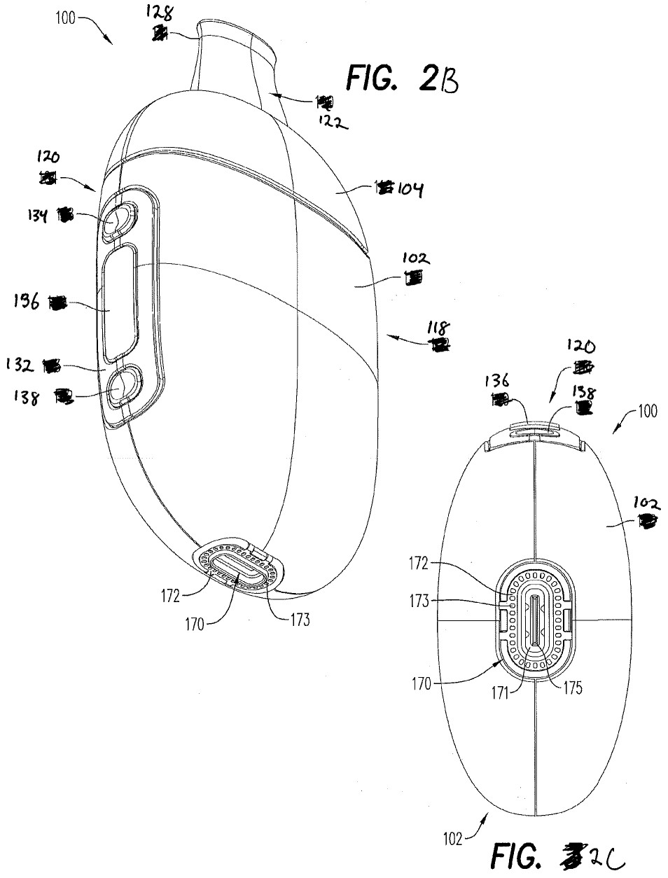

FIGS. 1, 2A, 2B, and 2C are illustrations of a device 100 according to some example embodiments. In some embodiments, the device 100 may be an aerosol-generating device. Referring to FIG. 1, a top perspective view of the device 100 is shown. In some embodiments, a main body of the device 100 may have a general oblong or pebble shape. The main body of the device 100 may include a housing 102 and a lid mechanism or a lid 104. The housing 102 may have a first end 106 and a second end 108 opposite the first end 106. The lid may have a first end 110 and a second end 112 opposite the first end 110. The first end 110 of the lid 104 may be fixedly coupled to the second end 108 of the housing 102 at a first point 114 and releasably couplable to the second end 108 of the housing 102 at a second point 116. The first point 114 of the housing 102 may be on a first side 118 of the device 100. The second point 116 of the housing 102 may be on a second side 120 of the device 100.

In some example embodiments, the device 100 may further include a mouthpiece 122. In at least some example embodiments, the mouthpiece 122 may include a first end 124 and a second end 126 opposite the first end 124. The second end 126 of the mouthpiece 122 may be coupled to the second end 112 of the lid 104. In some embodiments, the second end 126 of the mouthpiece 122 may be releasably coupled to the second end 112 of the lid 104. In at least one example embodiment, the mouthpiece 122 may be tapered between the first end 124 and the second end 126. For example, the diameter or average length/width dimensions of the first end 124 may be smaller than the diameter or average length/width dimensions of the second end 126. Towards the first end 124, the taper may have a slight inward curvature 128 that is configured to receive the lips of an adult consumer and improve the comfort and experience. In some embodiments, the first end 124 may have an oblong or elliptical shape and may include one or more outlets 130. For example, the first end 124 may include four outlets 130, such that four or more different areas or quadrants of the adult consumer's mouth can be engaged during use of the device 100. In other embodiments, the mouthpiece 122 may have fewer outlets than the four outlets 130 or more outlets than the four outlets 130.

In some example embodiments, the housing 102 may include an adult consumer interface panel 132 disposed on the second side 120 of the device 100. For example, the consumer interface panel 132 may be an oval-shaped panel that runs along the second side 120 of the device 100. The consumer interface panel 132 may include a latch release button 134, as well as a communication screen 136 and/or a control button 138. For example, in at least some example embodiments, the consumer interface panel 132 may include the communication screen 136 disposed between the latch release button 134 and the control button 138. As illustrated, the latch release button 134 may be disposed towards the second end 108 of the device 100, and the control button 138 may be disposed towards the first end 106 of the device 100. The latch release button 134 and the control button 138 may be adult consumer interaction buttons. The latch release button 134 and the control button 138 may have a substantially circular shape with a center depression or dimple configured to direct the pressure applied by the adult consumer, although example embodiments are not limited thereto. The control button 138 may turn on and off the device 100. Though only the two buttons are illustrated, it should be understood more or less buttons may be provided depending on the available features and desired adult consumer interface.

The communication screen 136 may be an adult consumer interface such as a human-machine interface (HMI) display. In at least one example embodiment, the communication screen 136 may be an integrated thin-film transistor (“TFT”) screen. In other example embodiments, the communication screen 136 is an organic light emitting diode (“OLED”) or light emitting diode (“LED”) screen. The communication screen 136 is configured for adult consumer engagement and may have a generally oblong shape.

In some embodiments, an exterior of the housing 102 and/or the lid 104 may be formed from a metal (such as aluminum, stainless steel, and the like); an aesthetic, food contact rated plastic (such as, a polycarbonate (PC), acrylonitrile butadiene styrene (ABS) material, liquid crystalline polymer (LCP), a copolyester plastic, or any other suitable polymer and/or plastic); or any combination thereof. The mouthpiece 122 may be similarly formed from a metal (such as aluminum, stainless steel, and the like); an aesthetic, food contact rated plastic (such as, a polycarbonate (PC), acrylonitrile butadiene styrene (ABS) material, liquid crystalline polymer (LCP), a copolyester plastic, or any other suitable polymer and/or plastic); and/or plant-based materials (such as wood, bamboo, and the like). One or more interior surfaces or the housing 102 and/or the lid 104 may be formed from or coated with a high temperature plastic (such as, polyetheretherketone (PEEK), liquid crystal polymer (LCP), or the like).

FIG. 2A shows another top perspective view of the device 100 with the lid 104 in an open configuration. The lid 104 may be fixedly coupled to the housing 102 at the first point 114 by a hinge 202, or other similar connector, that allows the lid 104 to move (e.g., swing and rotate) from an open position to a closed position. In some embodiments, the hinge 202 may be a torsion spring. In at least some example embodiments, the housing 102 may include a recess 204 at the first point 114. The recess 204 may be configured to receive a portion of the lid 104 so as to allow for an easy and smooth movement of the lid 104 from the open position to the closed position (and vice versa). The recess 204 may have a structure that corresponds with a relative portion of the lid 104. For example, as illustrated, the recess 204 may include a substantially curved portion 206 that has a general concave shape that corresponds with the curvature of the lid 104, which has a general convex shape.

The lid 104 may be releasably couplable to the housing 102 at the second point 116 by a latch 208, or other similar connector, that allows the lid 104 to be fixed or secured in the closed position and easily releasable to allow the lid 104 to move from the closed position to the open position. In at least one example embodiment, the latch 208 may be coupled to a latch release mechanism disposed within the housing. The latch release mechanism may be configured to move the latch 208 from a first or closed position to a second or open position.

When the lid 104 is in the open position as shown in FIG. 2A, a capsule receiving cavity 210 of the housing 102 is exposed. A capsule connector 212 may define the capsule receiving cavity 210 of the housing 102. In some embodiments, the capsule connector 212 may be mounted or otherwise secured to a printed circuit board (PCB) within the housing 102.

As shown in FIG. 2A, a capsule 214 may be received by the capsule receiving cavity 210. The capsule may house a consumable of the device 100. In some embodiments, not pictured herein, there may be a gasket disposed around the capsule 214 to help secure the capsule 214 in place within the housing 102. The capsule 214 may include a housing 216 configured to contain an aerosol-forming substrate and a heater. In some embodiments, the housing 216 may be in the form of a cover such as a shell or a box sleeve. In some embodiments, the capsule 214 can include a first end cap 217 and a second end cap. The second end cap may be opposite the first end cap 217 such that is disposed within the housing 102 when the capsule 214 is received by the capsule receiving cavity 210.

As discussed herein, an aerosol-forming substrate is a material or combination of materials that may yield an aerosol. An aerosol relates to the matter generated or output by the devices disclosed, claimed, and equivalents thereof. The material may include a compound (e.g., nicotine, cannabinoid), wherein an aerosol including the compound is produced when the material is heated. The heating may be below the combustion temperature so as to produce an aerosol without involving a substantial pyrolysis of the aerosol-forming substrate or the substantial generation of combustion byproducts (if any). Thus, in an example embodiment, pyrolysis does not occur during the heating and resulting production of aerosol. In other instances, there may be some pyrolysis and combustion byproducts, but the extent may be considered relatively minor and/or merely incidental.

The aerosol-forming substrate may be a fibrous material. For instance, the fibrous material may be a botanical material. The fibrous material is configured to release a compound when heated. The compound may be a naturally occurring constituent of the fibrous material. For instance, the fibrous material may be plant material such as tobacco, and the compound released may be nicotine. The term “tobacco” includes any tobacco plant material including tobacco leaf, tobacco plug, reconstituted tobacco, compressed tobacco, shaped tobacco, or powder tobacco, and combinations thereof from one or more species of tobacco plants, such as Nicotiana rustica and Nicotiana tabacum.

In some example embodiments, the tobacco material may include material from any member of the genus Nicotiana. In addition, the tobacco material may include a blend of two or more different tobacco varieties. Examples of suitable types of tobacco materials that may be used include, but are not limited to, flue-cured tobacco, Burley tobacco, Dark tobacco, Maryland tobacco, Oriental tobacco, rare tobacco, specialty tobacco, blends thereof, and the like. The tobacco material may be provided in any suitable form, including, but not limited to, tobacco lamina, processed tobacco materials, such as volume expanded or puffed tobacco, processed tobacco stems, such as cut-rolled or cut-puffed stems, reconstituted tobacco materials, blends thereof, and the like. In some example embodiments, the tobacco material is in the form of a substantially dry tobacco mass. Furthermore, in some instances, the tobacco material may be mixed and/or combined with at least one of propylene glycol, glycerin, sub-combinations thereof, or combinations thereof.

The compound may also be a naturally occurring constituent of a medicinal plant that has a medically-accepted therapeutic effect. For instance, the medicinal plant may be a cannabis plant, and the compound may be a cannabinoid. Cannabinoids interact with receptors in the body to produce a wide range of effects. As a result, cannabinoids have been used for a variety of medicinal purposes (e.g., treatment of pain, nausea, epilepsy, psychiatric disorders). The fibrous material may include the leaf and/or flower material from one or more species of cannabis plants such as Cannabis sativa, Cannabis indica, and Cannabis ruderalis. In some instances, the fibrous material is a mixture of 60-80% (e.g., 70%) Cannabis sativa and 20-40% (e.g., 30%) Cannabis indica.

Examples of cannabinoids include tetrahydrocannabinolic acid (THCA), tetrahydrocannabinol (THC), cannabidiolic acid (CBDA), cannabidiol (CBD), cannabinol (CBN), cannabicyclol (CBL), cannabichromene (CBC), and cannabigerol (CBG). Tetrahydrocannabinolic acid (THCA) is a precursor of tetrahydrocannabinol (THC), while cannabidiolic acid (CBDA) is precursor of cannabidiol (CBD). Tetrahydrocannabinolic acid (THCA) and cannabidiolic acid (CBDA) may be converted to tetrahydrocannabinol (THC) and cannabidiol (CBD), respectively, via heating. In an example embodiment, heat from a heater may cause decarboxylation so as to convert the tetrahydrocannabinolic acid (THCA) in the capsule to tetrahydrocannabinol (THC), and/or to convert the cannabidiolic acid (CBDA) in the capsule to cannabidiol (CBD).

In instances where both tetrahydrocannabinolic acid (THCA) and tetrahydrocannabinol (THC) are present in the capsule, the decarboxylation and resulting conversion will cause a decrease in tetrahydrocannabinolic acid (THCA) and an increase in tetrahydrocannabinol (THC). At least 50% (e.g., at least 87%) of the tetrahydrocannabinolic acid (THCA) may be converted to tetrahydrocannabinol (THC) during the heating of the capsule. Similarly, in instances where both cannabidiolic acid (CBDA) and cannabidiol (CBD) are present in the capsule, the decarboxylation and resulting conversion will cause a decrease in cannabidiolic acid (CBDA) and an increase in cannabidiol (CBD). At least 50% (e.g., at least 87%) of the cannabidiolic acid (CBDA) may be converted to cannabidiol (CBD) during the heating of the capsule.

Furthermore, the compound may be or may additionally include a non-naturally occurring additive that is subsequently introduced into the fibrous material. In one instance, the fibrous material may include at least one of cotton, polyethylene, polyester, rayon, combinations thereof, or the like (e.g., in a form of a gauze). In another instance, the fibrous material may be a cellulose material (e.g., non-tobacco and/or non-cannabis material). In either instance, the compound introduced may include nicotine, cannabinoids, and/or flavorants. The flavorants may be from natural sources, such as plant extracts (e.g., tobacco extract, cannabis extract), and/or artificial sources. In yet another instance, when the fibrous material includes tobacco and/or cannabis, the compound may be or may additionally include one or more flavorants (e.g., menthol, mint, vanilla). Thus, the compound within the aerosol-forming substrate may include naturally occurring constituents and/or non-naturally occurring additives. In this regard, it should be understood that existing levels of the naturally occurring constituents of the aerosol-forming substrate may be increased through supplementation. For example, the existing levels of nicotine in a quantity of tobacco may be increased through supplementation with an extract containing nicotine. Similarly, the existing levels of one or more cannabinoids in a quantity of cannabis may be increased through supplementation with an extract containing such cannabinoids.

The first end cap 217 can include a first opening 218. In some embodiments, the first opening 218 may be a series of openings disposed through the first end cap 217. Similarly, the second end cap can include a second opening that may be a series of openings in some embodiments. In some embodiments, the first end cap 217 and/or the second end cap may be transparent so as to serve as windows configured to permit a viewing of the contents/components (e.g., aerosol-forming substrate and/or heater) within the capsule 214.

The capsule receiving cavity 210 may have a base that may be inside the housing 102. In some embodiments, the base may include at least a first contact point and a second contact point that may each be configured to couple to one or more contact points of the capsule 214 when the capsule 214 is received by the capsule receiving cavity 210. A power may be applied to the first contact point, which may then be provided to the heater of the capsule 214.

When the capsule 214 is inserted into the capsule receiving cavity 210, the weight of the capsule 214 itself may not be sufficient to compress the first contact point and the second contact point of the base of the capsule receiving cavity 210. As a result, the capsule 214 may simply rest on exposed pins of the first contact point and the second contact point without any compression (or without any significant compression) of electrical contacts of the first contact point and the second contact point. Additionally, the weight of the lid 104 itself, when pivoted to transition to a closed position, may not compress the electrical contacts of the first contact point and the second contact point to any significant degree and, instead, may simply rest on the capsule 214 in an intermediate, partially open/closed position. In such an instance, a deliberate action (e.g., downward force) to close the lid 104 will cause a surface 220 of the lid 104 to press down onto the capsule 214 to provide the desired seal and also cause the capsule 214 to compress and, thus, fully engage the electrical contacts of the first contact point and the second contact point. When in the closed position, the lid 104 secures the capsule 214 within the device 100.

Additionally, a full closure of the lid 104 may result in an engagement with the latch 208, which may maintain the closed position and the desired mechanical/electrical engagements involving the capsule 214 until released (e.g., via the latch release button 134). The force requirement for closing the lid 104 may help to ensure and/or improve air/aerosol sealing and to provide a more robust electrical connection, as well as improved device and thermal efficiency and battery life by reducing or eliminating early power draws and/or parasitic heating of the capsule 214.

The lid 104 may include an inner cavity 222 that may be adapted to receive the housing 102 when the lid is in the closed position. In some embodiments, the inner cavity 222 of the lid 104 may include an impingement or engagement member or the surface 220 configured to engage the capsule 214 when the lid 104 is pivoted to transition to the closed position. The surface 220 of the lid 104 may include a recess that may correspond to the size and shape of the capsule and/or a resilient material to enhance an interface with the capsule to provide the desired seal. In some embodiments, the lid 104 may further include an opening 224 that may be adapted to receive the second end 126 of the mouthpiece 122. The mouthpiece 122 may include at least one extension 226 that may be received by the opening 224 of the lid 104 to secure the mouthpiece 122 to the lid 104. In some embodiments, the lid 104 may further include a projection that may be configured to couple with a recess 228 of the housing 102. The projection may fit within the recess 228 when the lid 104 is coupled to the housing 102 in the closed position.

In at least one example embodiment, illustrated in FIG. 2B, the housing 102 defines a charging connector or port 170. For example, the charging connector 170 may be defined/disposed in a bottom or second end of the housing 102 distal from the capsule receiving cavity 210. The charging connector 170 may be configured to receive an electric current (e.g., via a USB/mini-USB cable) from an external power source so as to charge the power source 150 internal to the aerosol-generating device 100. For example, in at least one example embodiment, such as best illustrated in FIG. 2C, the charging connector 170 may be an assembly defining a cavity 171 that has a projection 175 within the cavity 171. In at least one example embodiment, the projection 175 does not extend beyond the rim of the cavity 171. In addition, the charging connector 170 may also be configured to send data to and/or receive data (e.g., via a USB/mini-USB cable) from another aerosol generating device (e.g., heat not-burn (HNB) aerosol generating device) and/or other electronic device (e.g., phone, tablet, computer, and the like). In at least one embodiment, the device 100 may instead or additionally be configured for wireless communication (e.g., via Bluetooth) with such other aerosol generating devices and/or electronic devices.

In at least one example embodiment, such as best illustrated in FIG. 2C, a protective grille 172 is disposed around the charging connector 170. The protective grille 172 may be configured to help reduce or prevent debris ingress and/or the inadvertent blockage of the incoming airflow. For example, the protective grille 172 may define a plurality of pores 173 along its length or course. As illustrated, the protective grille 172 may have an annular form that surrounds the charging connector 170. In this regard, the pores 173 may also be arranged (e.g., in a serial arrangement) around the charging connector 170. Each of the pores 173 may have an oval or circular shape, although not limited thereto. In at least one example embodiment, the protective grille 172 may include an approved food contact material. For example, the protective grille 172 may include plastic, metal (e.g., stainless steel, aluminum), or any combination thereof. In at least one example embodiment, a surface of the protective grille 172 may be coated, for example with a thin layer of plastic, and/or anodized.

The pores 173 in the protective grille 172 may function as inlets for air drawn into the aerosol-generating device 100. During the operation of the aerosol-generating device 100, ambient air entering through the pores 173 in the protective grille 172 around the charging connector 170 will converge to form a combined flow that then travels to the capsule 214. For example, the pores 173 may be in fluidic communication with the capsule receiving cavity 210. In at least one example embodiment, air may be drawn from the pores 173 and through the capsule receiving cavity 210. For example, air may be drawn through the capsule 214 received by the capsule receiving cavity 210 and out of the replaceable mouthpiece 190.

As should be understood, the device 100 and capsule 214 include additional components (e.g., heater and internal air flow path) such as described in Atty. Docket No. 24000NV-000847-US, entitled “HEAT-NOT-BURN (HNB) AEROSOL-GENERATING DEVICES AND CAPSULES”, filed on the same day herewith and assigned application Ser. No. ______, the entire contents of which are herein incorporated by reference.

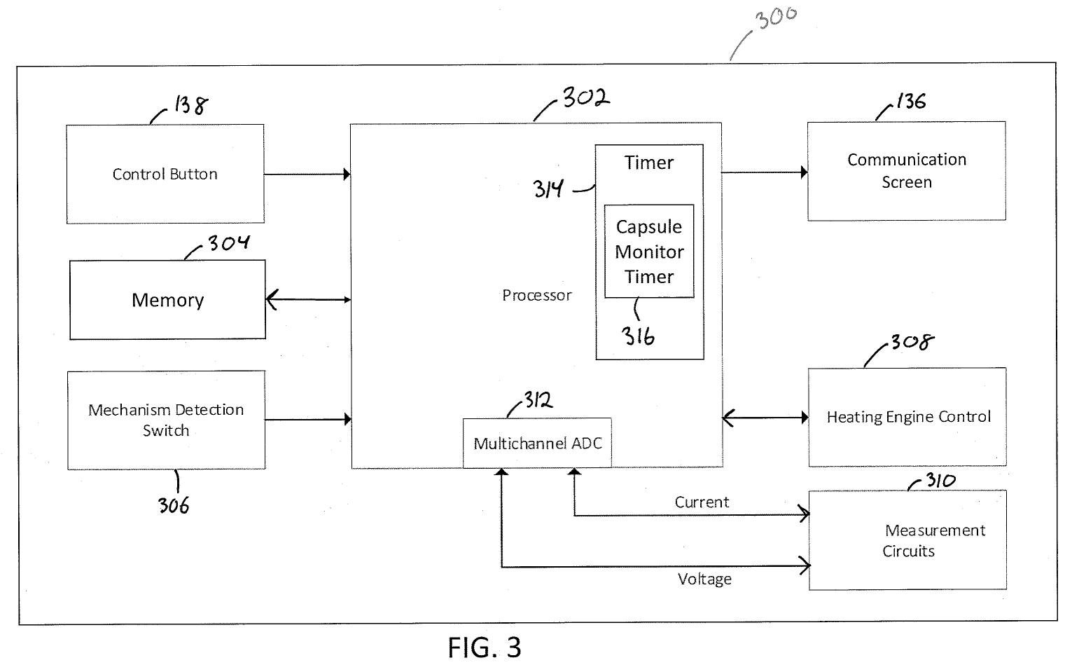

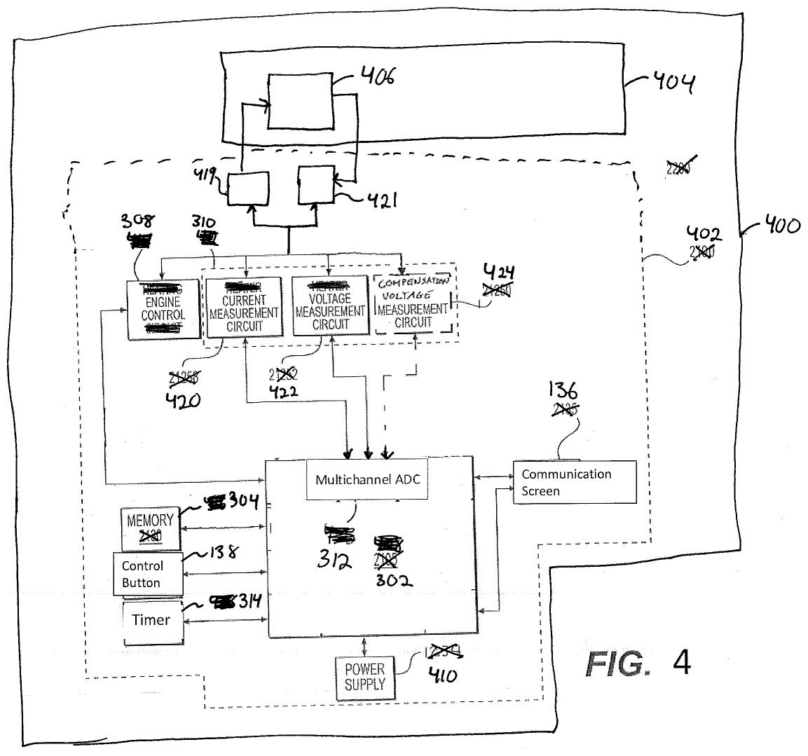

With reference to FIGS. 3 and 4, like reference numerals refer to like elements.

Referring to FIG. 3, a block diagram of a capsule monitoring system 300 of the device 100 according to an example embodiment is shown. In one example, the capsule monitoring system 300 is configured to determine a resistance between the first contact point of the device 100 and the second contact point of the device 100 when a power is applied. The capsule monitoring system 300 is configured to use the resistance between the first contact point and the second contact point to determine whether the capsule 214 has been inserted into the device 100 and, if the capsule 214 has been inserted into the device 100, whether the heater within the capsule 214 is operable within its operating specifications. The capsule monitoring system 300 may achieve this by comparing the resistance between the first contact point and second contact point with various ranges and thresholds based on operating specifications of the heater of the capsule 214.

The capsule monitoring system 300 may include a processor 302, a memory 304, a mechanism detection switch 306, the communication screen 136, a heating engine control 308, the control button 138, and measurement circuits 310. In some embodiments, the processor 302 may include a multichannel analog to digital converter (ADC) 312 and a timer 314. The processor 302 may communicate with the memory 304, the mechanism detection switch 306, the heating engine control 308, the communication screen 136, the control button 138, the measurement circuits 310, the multichannel ADC 312, and the timer 314.

The processor 302 may be hardware including logic circuits, a hardware/software combination that may be configured to execute software, a combination thereof. The processor 302 may be configured as a special purpose machine (e.g., a processing device) to execute the software or instructions, stored in the memory 304. The software may be embodied as program code including instructions for performing and/or controlling any or all operations described herein as being performed by the processor 302.

While the timer 314 is shown within the processor, it should be understood that the timer may be external to the processor 302.

The memory 304 may describe any of the terms “storage medium”, “computer readable storage medium” or “non-transitory computer readable storage medium” and may represent one or more devices for storing data, including read only memory (ROM), random access memory (RAM), magnetic RAM, core memory, magnetic disk storage mediums, optical storage mediums, flash memory devices and/or other tangible machine-readable mediums for storing information. The term “computer-readable medium” may include, but is not limited to, portable or fixed storage devices, optical storage devices, and various other mediums capable of storing, containing, or carrying instructions and/or data. The memory 304 may store operational parameters and computer readable instructions for the processor 302 to perform the algorithms described herein. The memory 304 may store values determined throughout operation of the capsule monitoring system 300, such as determined resistances. The memory 304 is illustrated as being external to the processor 302, but in some example embodiments, the memory 304 may be on board the processor 302.

The timer 314 may be a timing mechanism, such as an oscillator circuit, to enable the processor 302 to measure times related to operation of the device, such as a session time, a capsule monitor time, or the like, of the device 100.

The timer 314 may include one or more timers configured to measure one or more times related to the device 100 and/or the capsule monitoring system 300. The timer 314 may include a capsule monitor timer 316 that may be configured to measure capsule monitor time. The capsule monitor time may be a length of time a startup power is applied to the first contact point. The capsule monitor time may be a length of time of a startup monitoring operation. The capsule monitor timer 316 may be configured to be reset when a capsule monitoring system 300 detects the mechanism detection switch 306 has been activated.

The mechanism detection switch 306 may be configured to be activated when the lid 104 of the device 100 has been latched. In some embodiments, the mechanism detection switch 306 may be configured to be actuated when the second point 116 is coupled to the latch 208 when the lid 104 is placed in a closed position, such as when an adult consumer closes the lid 104. In other words, activation of the mechanism detection switch 306 may occur when an adult consumer closes the lid 104. Such a closure may occur after an adult consumer has inserted the capsule 214 into the capsule receiving cavity 210 of the device 100.

The communication screen 136 may be configured to display information related to the device 100. The communication screen 136 may be configured to display one or more icons to communicate information related to the device 100. For example, the communication screen 136 may be configured to display a fault indicator that may indicate to an adult consumer the capsule 214 cannot operate properly and should be removed from the device 100. In some embodiments, the communication screen 136 may be configured to display a capsule accepted indicator that may indicate to an adult consumer the capsule 214 was detected in the device 100 and the heater of the capsule 214 was found to be properly operable in accordance with the heater's operating specifications during the startup monitoring operation.

The control button 138 may be configured to generate a signal indicating that an adult consumer has switched the device 100 to an “on” state or to an “off” state. When the device 100 is switched to an “on” state, the device 100 may begin to preheat. In some embodiments, a session may start once the control button 138 is pressed.

The heating engine control 308 may be communicatively coupled with the heater of the device 100. The heating engine control 308 may be configured to turn on the heater when the control button 138 detects that the device 100 has been powered on. The heating engine control 308 may additionally be configured to turn off the heater of the device 100 when a capsule fault has been detected by the capsule monitoring system 300.

The measurement circuits 310 may include a plurality of sensor or measurement circuits configured to provide signals indicative of sensor or measurement information to the processor 302. In the example shown in FIG. 3, the measurement circuits 310 provide current and voltage sensor or measurement information to the processor 302.

The measurement circuits 310 are connected to the processor 302 through respective pins of the multichannel ADC 312. In some embodiments, there may be multiple multichannel ADCs 312, such that each multichannel ADC 312 may be connected to one or more measurement circuits 310. The voltage and current sensor or measurement information may be used by the processor 302 to determine the startup resistance and the preheat resistance between the first contact point and the second contact point. For example, the processor may utilize either of the following equations to determine the startup resistance and the preheat resistance between the first contact point and the second contact point:

R_{ConPts}=V_{ConPts}/I_{ConPts}

P_{ConPts}=I_{ConPts}²*R_{ConPts}

where R_{ConPts} is the resistance determination, V_{ConPts} is the voltage measured by the measurement circuits 310, I_{ConPts} is the voltage measured by the measurement circuits 310, and P_{ConPts} is the power applied to the first contact point. The multichannel ADC 312 of the processor 302 may sample the output signals from the measurement circuits 310 at a sampling rate appropriate for the given characteristic and/or parameter being measured by the respective measurement circuits 310. In some embodiments, the processor 302 may average resistances calculated from the most recent 16 samples. Such an average may be the resistance determination. Further detail regarding the measurement circuits 310 is provided below with reference to FIG. 4.

With regards to the description of the capsule monitoring system 300 below, processing circuitry (e.g., the processor 302) may set the various time, power, and resistance thresholds and apply the power levels (via the heating engine control) to the heater. References to “startup” parameters of the capsule monitoring system 300 may also be known as “first” parameters (e.g., startup power may be the first power, startup resistance may be the first resistance).

The processor 302 may determine a startup resistance while a startup power is applied to the first contact point by the capsule monitoring system 300 during the startup monitoring operation. The startup power may be applied following activation of the mechanism detection switch 306, in order to determine whether the capsule 214 is present in the device and whether the heater of the capsule 214 is operating within resistance settings proscribed for the heater. The capsule monitoring system 300 may monitor the startup resistance periodically at a first time interval, such that one first time interval passes between determinations of the startup resistance. The first time interval may be about 1 millisecond.

The startup power may be increased by the processor 302 throughout the startup monitoring operation of the capsule monitoring system 300. The startup power may be increased by a startup power interval at a second time interval by the processor 302. The second time interval may be the same or substantially the same length of time as the first time interval. The second time interval may be about 1 millisecond. For example, if the startup power interval is 0.01 watts and the second time interval is 1 millisecond, the startup power will increase by 0.01 watts each millisecond.

In some embodiments, the processor 302 may monitor the startup power against a startup power threshold. The startup power threshold may be a given, desired, or alternatively, predetermined, amount of power which may produce a stable, relatively stable or substantially stable resistance reading. The capsule monitoring system 300 may cease applying the startup power to the first contact point when the startup power exceeds the startup power threshold. In some embodiments, the startup power threshold may be about 2 watts.

In some embodiments the processor 302 may monitor the capsule monitor time against a time threshold. The time threshold may be a given, desired, or alternatively, predetermined, time limit for the startup power to meet or exceed the startup power threshold during the startup monitoring operation. The capsule monitoring system 300 may cease applying the startup power to the first contact point when the capsule monitor time exceeds the time threshold. The time threshold may be equal or substantially equal to an amount of time required for the startup power to increase to a maximum power. In some embodiments, the time threshold may be about 217 milliseconds.

In some embodiments, the processor 302 may determine whether the startup resistance is within a resistance operation range. The resistance operation range is a range of resistances across the heater which are within operating specifications of the heater. The resistance operation range may be expanded to account for measurement accuracy and/or contact resistances. In some embodiments, a lower bound of the resistance operation range may be about 2002 milliohms, where the lower bound of the resistance operation range is included in the resistance operation range. In some embodiments, an upper bound of the resistance operation range may be about 2418 milliohms, where the upper bound of the resistance operation range is included in the resistance operation range.

In some embodiments, the processor 302 may monitor the startup resistance against a maximum heater resistance. The maximum heater resistance may be an expected resistance across the heater while the heater is experiencing a maximum temperature that is likely to occur during use of the device 100, as determined by the processor 302. The maximum temperature that the heater is likely to experience may be a high temperature shutoff temperature of the device 100. In some embodiments, the maximum heater resistance may be further increased to account for variations in the resistance and/or to accommodate minor variations in a temperature coefficient of resistance (TCR) for materials used in the heater. If the startup resistance exceeds the maximum heater resistance during the startup monitoring operation, then the capsule monitoring system 300 does not detect the presence of the capsule and the heater in the device 100 due to the startup resistance exceeding the maximum resistance that may occur with the presence of a heater. In some embodiments, the maximum heater resistance may be 3327 milliohms.

In some embodiments, the processor 302 may determine whether the startup resistance is within the resistance range. The resistance range is a range of resistances across the heater which are within limits of operation of the device 100. In some embodiments, a lower bound of the resistance range may be about half of a minimum heater operation resistance, where the lower bound of the resistance range is included in the resistance range. In some embodiments, the minimum heater operation resistance may be about 2002 milliohms. In some embodiments, the upper bound of the resistance range may be substantially equal to the maximum heater resistance, where the upper bound of the resistance range is included within the resistance range.

The processor 302 may determine a preheat resistance while a preheat power is applied to the first contact point during a preheat monitoring operation. The preheat power may only be applied after the capsule monitoring system 300 has detected the presence of the capsule 214 within the device 100 during the startup monitoring operation. The processor 302 may monitor the preheat resistance periodically at a third time interval, such that one third time interval passes between determinations of the preheat resistance. The third time interval may be about 1 millisecond.

The preheat power may be applied following an adult consumer of the device initiating a session of the device. The preheat power is applied to the heater to heat the consumables within the capsule 214 in preparation for use of the device 100. The preheat power may be increased throughout the preheat monitoring operation of the capsule monitoring system 300 by the processor 302. The preheat power may be increased by a preheat power interval at a fourth time interval. The fourth time interval may be the same or substantially the same length of time as the third time interval. The fourth time interval may be about 1 millisecond. For example, if the preheat power interval is 0.01 watts and the fourth time interval is 1 millisecond, the preheat power will increase by 0.01 watts each millisecond.

The processor 302 may compare the preheat resistance to the startup resistance to determine whether electrical connections between the first and/or second contact points and the heater are stable, relatively stable or substantially stable. In some embodiments, the capsule monitoring system 300 may end the session or prevent a session from beginning after detecting issues are present in the heater or the electrical connections. In some embodiments, the capsule monitoring system 300 may alert the adult consumer of such an issue by displaying a fault indicator. In some embodiments, the processor 302 may determine whether the preheat resistance is within a resistance tolerance range. The resistance tolerance range is a range of resistance values based on the startup resistance stored in the memory 304 of the capsule monitoring system 300. When the preheat resistance is within the resistance tolerance range, the electrical connections between the first and/or second contact points and the heater are stable, relatively stable or substantially stable. In some embodiments, bounds of the resistance tolerance range may be about 15 milliohms above and about 15 milliohms below the startup resistance, where the bounds of the resistance tolerance range are included in the resistance tolerance range. In some embodiments, bounds of the resistance tolerance range may be about 30 milliohms above and about 30 milliohms below the startup resistance, where the bounds of the resistance tolerance range are included in the resistance tolerance range.

In some embodiments, the processor 302 may monitor the preheat power against a preheat power threshold. The preheat power threshold may be an amount of power which may produce a stable, relatively stable or substantially stable resistance reading. In some embodiments, the preheat power threshold may substantially be the same as the startup power threshold. In some embodiments, the preheat power threshold may be about 2 watts.

In some embodiments, the processor 302 may determine whether the preheat resistance is within the resistance range.

In some embodiments, the capsule monitoring system 300 may determine that no capsule 214 has been inserted into the device 100. In such embodiments, the capsule monitoring system 300 may return the device 100 to normal operation. When the device 100 is returned to normal operation by the capsule monitoring system 300, the device 100 may continue in the operation that was occurring prior to the detection the capsule 214 not being inserted. In some embodiments, this may include the communication screen 136 remaining off and not providing a notification to the adult consumer. In some embodiments, when the device 100 was performing a preheat operation prior to the preheat monitoring operation initiating, the device 100 may return to the preheat operation (i.e., the normal operation) after determining the preheat resistance is within the resistance tolerance range.

FIG. 4 illustrates a heating system 400 of the device 100 and the capsule 214 according to one or more example embodiments.

Referring to FIG. 4, the heating system 400 includes a device heating system 402 and a capsule heating system 404. The device heating system 402 may be included in the device 100, and the capsule heating system 404 may be included in the capsule 214.

The capsule heating system 404 may include a body electrical/data interface (not shown) for transferring power and/or data between the device 100 and the capsule 214. According to at least one example embodiment, electrical contacts may serve as the body electrical interface, but example embodiments are not limited thereto.

The device heating system 402 includes a processor 302, a power supply 410, measurement circuits 310, a heating engine control 308, the communication screen 136, the control button 138, a memory 304, and a timer 314. The device heating system 402 may further include a first contact point 419 and a second contact point 421 for providing power from the device 100 to the capsule 214. The processor 302 may further include a multichannel ADC 423. The processor 302 is communicatively coupled to the device sensors 310, the heating engine control 308, the communication screen 136, the memory 304, the control button 138, the timer 314 and the power supply 410.

The power supply 410 may be an internal power supply to supply power to the device 100 and the capsule 214. The supply of power from the power supply 410 may be controlled by the processor 302 through device power control circuitry (not shown). The power control circuitry may include one or more switches or transistors to regulate power output from the power supply 410. The power supply 410 may be a Lithium-ion battery or a variant thereof (e.g., a Lithium-ion polymer battery).

In the example embodiment shown in FIG. 4, the measurement circuits 310 may include a current measurement circuit 420, a voltage measurement circuit 422, and a compensation voltage measurement circuit 424. The measurement circuits 310 may be configured the same as the measurement circuits 310 as described above in reference to FIG. 3. The measurement circuits 310 may be connected to the processor 302 through respective pins of the multichannel ADC 423.

The current measurement circuit 420 may be configured to output (e.g., voltage) signals indicative of the current at the first contact point 419 and/or the second contact point 421. The voltage measurement circuit 422 may be configured to output (e.g., voltage) signals indicative of the voltage between the first contact point 419 and the second contact point 421, which may be the voltage across the heater 406 when the heater is present in the device 100. The current and/or the voltage may be used to determine characteristics, such as resistance between the first contact point 419 and the second contact point 421.

The compensation voltage measurement circuit 424 may be configured to output (e.g., voltage) signals indicative of the resistance of electrical connections between the capsule 214 and the device 100. In some example embodiments, the compensation voltage measurement circuit 424 may provide compensation voltage measurement signals to the processor 302, which may be used to calculate a corrected power to apply to the first contact point.

To measure characteristics and/or parameters of the device 100 and the capsule 214 (e.g., voltage, current, resistance, temperature, or the like, of the heater 406), the processor 302 may sample the output signals from the device sensors 310 at a sampling rate appropriate for the given characteristic and/or parameter being measured by the respective device sensor. In some embodiments, the sampling rate of the output signals from the device sensors may be the same as the first time interval of the capsule monitoring system 300 and the third time interval of the capsule monitoring system, as used during the startup monitoring operation and the preheat monitoring operation, respectively.

Additional details and/or alternatives for the voltage measurement circuit, current measurement circuit, and/or the compensation voltage measurement circuit may be found in U.S. application Ser. No. 17/151,409, titled “Heat-Not-Burn (HNB) Aerosol-Generating Devices Including Intra-Draw Heater Control, and Methods of Controlling a Heater” (Atty. Dkt. No. 24000NV-000670-US), filed on Jan. 18, 2021, the entire contents of which are incorporated herein by reference.

Still referring to FIG. 4, the processor 302 may control power to the first contact point 419, which is provided to the heater 406, to heat the aerosol-forming substrate in accordance with a heating profile (e.g., heating based on volume, temperature, flavor, or the like) during the preheat monitoring operation. The heating profile may be determined based on empirical data and may be stored in the memory 304 of the device 100.

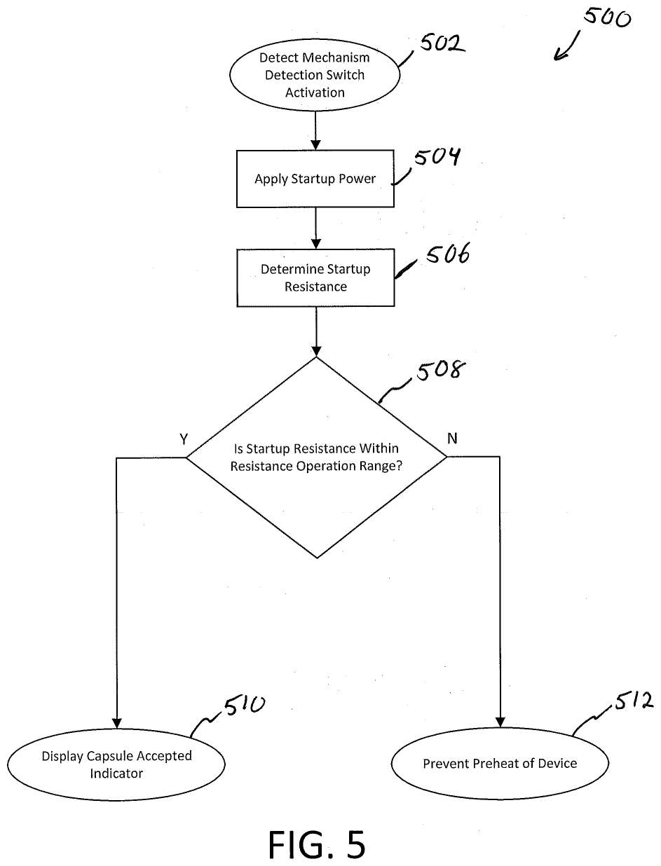

Referring to FIG. 5, a flow chart illustrating a method 500 of operating the capsule monitoring system 300 of the device, including the startup monitoring operation, is shown. The method 500 of FIG. 5 may be performed by the processor 302, for example. Steps identified as being executed processor 302 in the description below may be executed by other elements of the capsule monitoring system 300 in some embodiments. For example purposes, the method 500 shown in FIG. 5 will be discussed with regard to the example embodiments shown in FIGS. 3 and/or 4. However, example embodiments should not be limited to these examples.

In FIG. 5, the method 500 begins at step 502 when the capsule monitoring system 300 detects the mechanism detection switch 306 is activated.

The capsule monitoring system 300 then applies the startup power to the first contact point at step 504. At step 506, the startup resistance is determined by the capsule monitoring system 300 while the startup power is applied to the first contact point. The startup resistance may be determined by the processor 302 based on sensor or measurement information provided by the measurement circuits 310.

The method 500 then proceeds to conditional step 508, where the processor 302 determines whether the startup resistance is within a resistance operation range.

If the processor 302 determines at the conditional step 508 that the startup resistance is within the resistance operation range, then the method 500 proceeds to step 510, where the capsule monitoring system 300 displays a capsule accepted indicator. The capsule accepted indicator may be displayed on the communication screen 136 of the capsule monitoring system 300.

Returning to the conditional step 508, if the processor 302 determines at the conditional step 508 that the startup resistance is not within the resistance operation range, then the method 500 proceeds to step 512, where the capsule monitoring system 300 prevents preheating of the device 100.

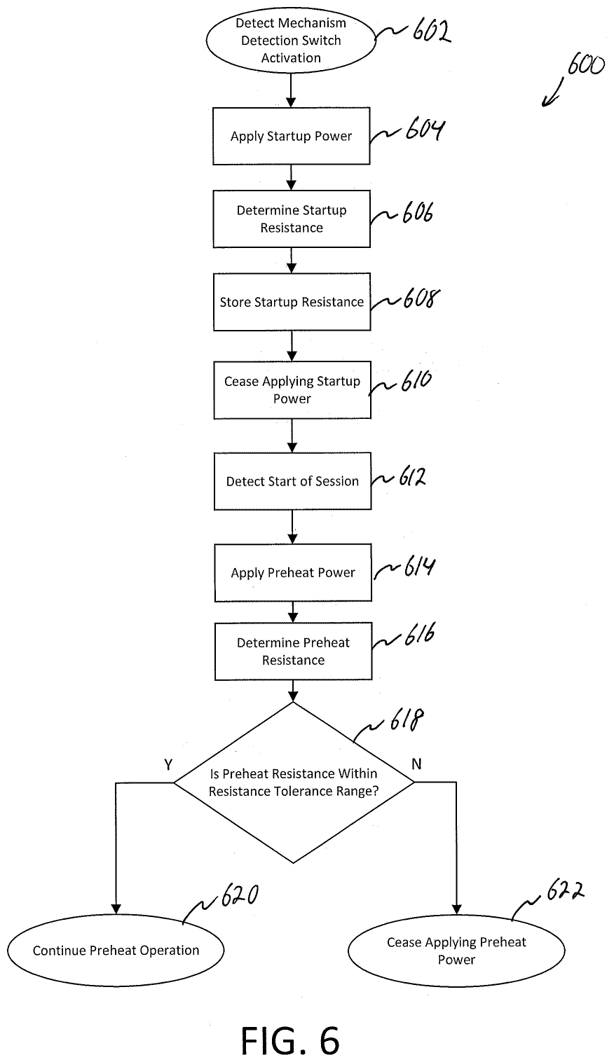

Referring to FIG. 6, a flow chart illustrating a method 600 of operating the capsule monitoring system 300 of the device, including the startup monitoring operation and the preheat monitoring operation, is shown. The method 600 of FIG. 6 may be performed by the processor 302, for example. Steps identified as being executed processor 302 in the description below may be executed by other elements of the capsule monitoring system 300 in some embodiments. For example purposes, the method 600 shown in FIG. 6 will be discussed with regard to the example embodiments shown in FIGS. 3 and/or 4. However, example embodiments should not be limited to these examples.

In FIG. 6, the method 600 begins at step 602 when the capsule monitoring system 300 detects the mechanism detection switch 306 is activated. The step 602 may be the beginning of the startup monitoring operation.

The capsule monitoring system 300 then applies the startup power to the first contact point at step 604.

At step 606, the startup resistance is determined by the processor 302.

After the processor 302 has determined the startup resistance, the capsule monitoring system 300 then stores the startup resistance in the memory 304 of the capsule monitoring system 300 at step 608. The capsule monitoring system 300 ceases applying the startup power to the first contact point at step 610 and end the startup monitoring operation.

Following the step 610, the capsule monitoring system 300 detects a start of a session of the device 100 at step 612, which is the beginning of the preheat monitoring operation and of a preheat operation of the session. The preheat operation of the session heats the consumables within the capsule 214 in preparation for operation of the device 100 by the adult consumer. The start of the session may occur when an adult consumer actuates the control button 138.

The method 600 then proceeds to step 614, where the capsule monitoring system 300 applies the preheat power to the first contact point. The method 600 then proceeds to step 616, where the processor 302 determines the preheat resistance.

The method 600 then proceeds to conditional step 618, where the processor 302 determines whether the preheat resistance is within the resistance tolerance range.

If the processor 302 determines at the conditional step 618 that the preheat resistance is within the resistance tolerance range, then the method 600 proceeds to step 620 and the capsule monitoring system 300 continues the preheat operation for the session. Continuing the preheat operation of the session at the step 620 ends the preheat monitoring operation.

Returning to the conditional step 618, if the processor 302 determines that the preheat resistance is not within the resistance tolerance range, then the method proceeds to step 622 where the capsule monitoring system 300 ceases applying the preheat power to the first contact point, ending the preheat monitoring operation.

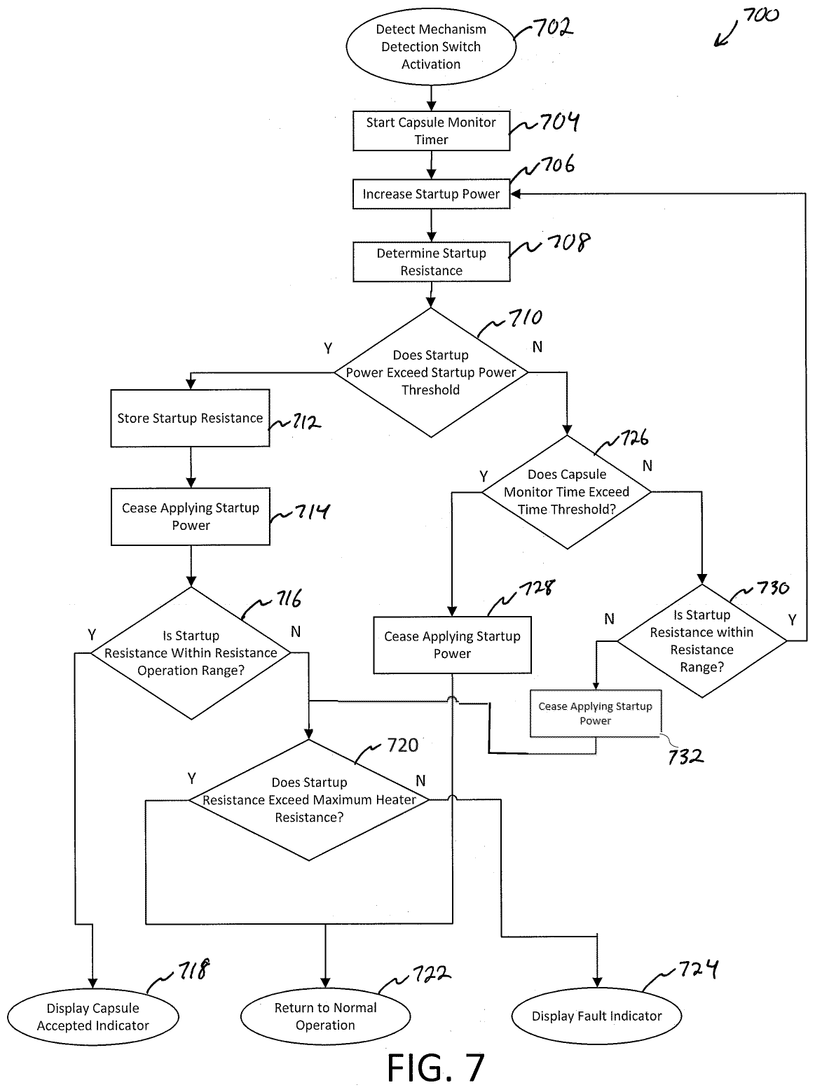

Referring to FIG. 7, a flow chart illustrating a method 700 of operating the capsule monitoring system 300 of the device, including the startup monitoring operation, is shown. The method 700 of FIG. 7 may be performed by the processor 302, for example. Steps identified as being executed processor 302 in the description below may be executed by other elements of the capsule monitoring system 300 in some embodiments. For example purposes, the method 700 shown in FIG. 7 will be discussed with regard to the example embodiments shown in FIGS. 3 and/or 4. However, example embodiments should not be limited to these examples.

In FIG. 7, the method 700 begins at step 702 when the capsule monitoring system 300 detects the mechanism detection switch 306 is activated. The detection of the mechanism detection switch 306 being activated is the beginning of the startup monitoring operation.

The method then proceeds to step 704 where the processor 302 starts the capsule monitor timer.

The method 700 then proceeds to step 706, where the capsule monitoring system 300 increases the startup power applied to the first contact point by the startup power interval.

The method 700 then proceeds to step 708 where the processor 302 determines the startup resistance.

After the startup resistance is determined, the processor 302 determines whether the startup power exceeds the startup power threshold at conditional step 710.

If the processor 302 determines the startup power exceeds the startup power threshold at the conditional step 710, the capsule monitoring system 300 stores the startup resistance in the memory 304 of the capsule monitoring system 300 at step 712.

Next, at step 714, the capsule monitoring system 300 ceases applying the startup power to the first contact point.

The method 700 then proceeds to conditional step 716, where the processor 302 determines whether the startup resistance is within the resistance operation range.

If the processor 302 determines the startup resistance is within the resistance operation range at the conditional step 716, then the method 700 proceeds to step 718 where the capsule monitoring system 300 displays the capsule accepted indicator. The method 700 will reach the step 718 when an in-specification heater of the capsule 214 is present in the device 100. The startup monitoring operation ends when the capsule accepted indicator is displayed at the step 718. After the capsule accepted indicator has been displayed at the step 718, the device 100 may be ready to receive direction to begin a session and the preheat monitoring operation.

Returning to the conditional step 716, if the processor 302 determines the startup resistance is not within the resistance operation range, then the method 700 proceeds to conditional step 720.

At the conditional step 720, the processor 302 determines whether the startup resistance exceeds the maximum heater resistance.

If the processor 302 determines the startup resistance exceeds the maximum heater resistance at the conditional step 720, then the capsule monitoring system 300 returns the device 100 to normal operation at step 722. Returning to normal operation at the step 722 ends the startup monitoring operation, as the capsule monitoring system 300 did not detect the capsule 214 present in the device 100. In some embodiments, normal operation at the step 722 may allow an adult consumer to insert the capsule 214 into the device 100 in order to continue operating the device 100.

Returning to the step 720, if the processor 302 determines the startup resistance does not exceed the maximum heater resistance, then the method 700 proceeds to step 724.

At the step 724, the capsule monitoring system 300 displays the fault indicator, as the capsule monitoring system 300 may have detected an issue with the heater within the capsule 214. Displaying the fault indicator at the step 724 ends the startup monitoring operation. Displaying the fault indicator may direct an adult consumer to remove and replace the capsule 214.

Returning to the conditional step 710, if the processor 302 determines the startup power does not exceed the startup power threshold, then the method 700 proceeds to conditional step 726.

At the conditional step 726, the processor 302 determines whether the capsule monitor time exceeds the time threshold.

If the processor 302 determines the capsule monitor time exceeds the time threshold, the method proceeds to step 728.

At the step 728, the capsule monitoring system 300 ceases applying the startup power to the first contact point. Next, the method 700 proceeds to the step 722 where the capsule monitoring system 300 returns the device 100 to normal operation, as the capsule monitoring system 300 does not detect the capsule 214 as present within the device 100.

Returning to the step 726, if the capsule monitoring system 300 determines that capsule monitor time does not exceed the time threshold, then the method 700 proceeds to conditional step 730.

At the conditional step 730, the processor 302 determines whether the startup resistance is within the resistance range.

If the processor 302 determines at the conditional step 730 that the startup resistance is not within the resistance range, then the method 700 proceeds to step 732.

At the step 732, the capsule monitoring system 300 ceases applying the startup power to the first contact point.

Next, the method 700 proceeds to the conditional step 720, where the processor 302 determines whether the startup resistance exceeds the maximum heater resistance.

If the processor 302 determines the startup resistance exceeds the maximum heater resistance at the conditional step 720, then the capsule monitoring system 300 returns the device 100 to normal operation at the step 722. Returning to normal operation at the step 722 ends the startup monitoring operation, as the capsule monitoring system 300 did not detect the capsule 214 present in the device 100. In some embodiments, normal operation at the step 722 may allow an adult consumer to insert the capsule 214 into the device 100 in order to continue operating the device 100.

Returning to step 720, if the processor 302 determines the startup resistance does not exceed the maximum heater resistance, then the method 700 proceeds to the step 724.

At the step 724, the capsule monitoring system 300 displays the fault indicator, as the capsule monitoring system 300 may have detected an issue with the heater within the capsule 214. Displaying the fault indicator at the step 724 ends the startup monitoring operation. Displaying the fault indicator may direct an adult consumer to remove and replace the capsule 214.

Returning to the conditional step 730, if the processor 302 determines that the startup resistance is within the resistance range, then the method 700 proceeds to the step 706 where the capsule monitoring system 300 increases the startup power applied to the first contact point by the startup power interval. The startup power applied to the first contact point may be increased after the second time interval has passed since the previous increase of the startup power applied to the first contact point.

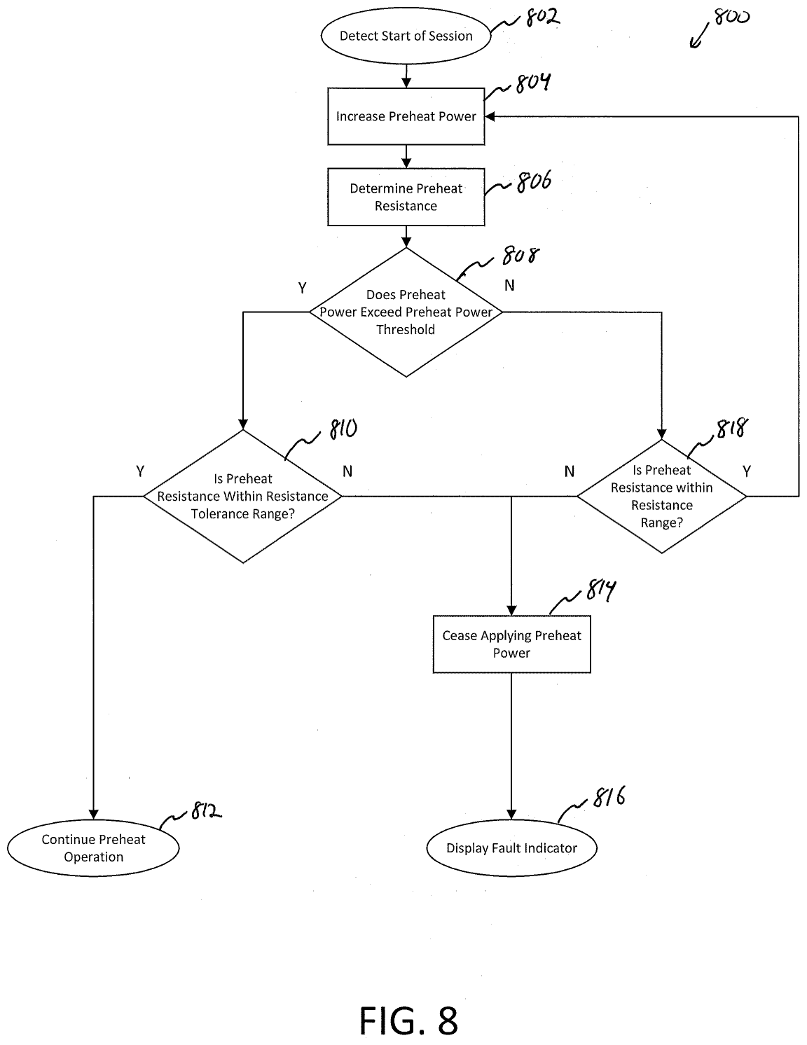

Referring to FIG. 8, a flow chart illustrating a method 800 of operating of the capsule monitoring system 300 of the device, including the preheat monitoring operation, is shown. The method 800 of FIG. 8 may be performed by the processor 302, for example. Steps identified as being executed processor 302 in the description below may be executed by other elements of the capsule monitoring system 300 in some embodiments. For example purposes, the method 800 shown in FIG. 8 will be discussed with regard to the example embodiments shown in FIGS. 3 and/or 4. However, example embodiments should not be limited to these examples. The method 800 in FIG. 8 may occur after the startup monitoring operation shown in the method 700 in FIG. 7 has ended at the step 718.

In FIG. 8, the method 800 begins at step 802 when the capsule monitoring system 300 detects a session of the device 100 is initiated. The session may be initiated by an adult consumer actuating the control button 138.

The method 800 then proceeds to step 804 where the capsule monitoring system 300 increases the preheat power applied to the first contact point by the preheat power interval.

The method 800 then proceeds to step 806, where the processor 302 determines the preheat resistance. After the startup resistance is determined at the step 806, the processor 302 determines whether the preheat power exceeds the preheat power threshold at conditional step 808.

If the processor 302 determines the preheat power exceeds the preheat power threshold at the conditional step 808, then the processor 302 determines whether the preheat power is within the resistance tolerance range at conditional step 810.

If the processor 302 determines at the conditional step 810 that the preheat power is within the resistance tolerance range, then the method 800 proceeds to step 812 where the capsule monitoring system 300 continues the preheat operation of the device 100 previously started by the adult consumer initiating the session. The step 812 ends the preheat monitoring operation and continues the session of the device 100.

Returning to the conditional step 810, if the capsule monitoring system 300 determines that the preheat power is not within the resistance tolerance range, then the capsule monitoring system 300 ceases providing the preheat power to the first contact point at step 814.

Next, at step 816, the capsule monitoring system displays the fault indicator, ending the preheat monitoring operation due to the capsule monitoring system 300 detecting an issue with the heater or the electrical connections between the first and/or second contact points and the heater. Displaying the fault indicator may direct an adult consumer to remove and replace the capsule 214. The step 816 ends the preheat monitoring operation and ends the session of the device 100.

Returning to the conditional step 808, if the processor 302 determines the preheat power does not exceed the preheat power threshold, then the method 800 proceeds to conditional step 818.

At the conditional step 818, the processor 302 determines whether the preheat resistance is within the resistance range.

If the processor 302 determines at the conditional step 818 that the startup resistance is not within the resistance range, then the method 800 proceeds to the step 814.

At the step 814, the capsule monitoring system 300 ceases providing the preheat power to the first contact point. Next, the method 800 proceeds to the step 816, where the capsule monitoring system 300 displays the fault indicator due to the capsule monitoring system 300 detecting an issue with the heater or the electrical connections between the first and/or second contact points and the heater. Displaying the fault indicator may direct an adult consumer to remove and replace the capsule 214. The step 816 ends the preheat monitoring operation and ends the session of the device 100.

Returning to the conditional step 818, if the processor 302 determines that the startup resistance is within the resistance range, then the method 800 proceeds to the step 804 where the capsule monitoring system 300 increases the preheat power applied to the first contact point by the preheat power interval. The preheat power applied to the first contact point may be increased after the fourth time interval has passed since the previous increase of the preheat power applied to the first contact point.

The systems, apparatuses, and methods described herein may provide one or more advantages. The capsule monitoring system 300 may provide a way for the device 100 to detect whether the capsule has been inserted into the device 100 without the need for a sensor to detect a presence of the capsule 214 in the device 100. The capsule monitoring system 300 may also monitor for issues of the heater of the capsule 214 that would prevent a desired sensory experience for the adult consumer. Further, the capsule monitoring system 300 may detect when the electrical connections between the first and/or second contact points and the heater are not stable. Additionally, the capsule monitoring system 300 may provide a way to communicate an issue with the heater of the capsule 214 or with the electrical connections of the first and/or second contact points and the heater to an adult consumer. Such a communication may direct an adult consumer to remove and replace the capsule 214.

The appended claims set forth novel and inventive aspects of the subject matter described above, but the claims may also encompass additional subject matter not specifically recited in detail. For example, certain features, elements, or aspects may be omitted from the claims if not necessary to distinguish the novel and inventive features from what is already known to a person having ordinary skill in the art. Features, elements, and aspects described in the context of some embodiments may also be omitted, combined, or replaced by alternative features serving the same, equivalent, or similar purpose without departing from the scope of the invention defined by the appended claims.

What is claimed is:

1. A capsule monitoring system for an aerosol-generating device, the capsule monitoring system comprising:
at least one processor; and
a memory coupled to the at least one processor and storing instructions,
wherein the at least one processor is configured to execute the instructions to cause the capsule monitoring system to,
detect actuation of a mechanism detection switch of the aerosol-generating device,
apply a first power to a first contact point of the aerosol-generating device,
determine a first resistance between the first contact point and a second contact point, the first contact point and the second contact point configured to contact a heater,
determine whether the first resistance is within a resistance operation range, and
display a capsule accepted indicator in response to the first resistance being within the resistance operation range.

2. The capsule monitoring system of claim 1, wherein the at least one processor is configured to execute the instructions to cause the capsule monitoring system to,
start a capsule monitor timer configured to measure a capsule monitor time, and
to reset the capsule monitor timer in response to actuation of the mechanism detection switch.

3. The capsule monitoring system of claim 2, wherein the at least one processor is configured to execute the instructions to cause the capsule monitoring system to increase the first power until the first power exceeds a first power threshold.

4. The capsule monitoring system of claim 3, wherein the at least one processor is configured to execute the instructions to cause the capsule monitoring system to,
monitor the first power relative to the first power threshold,
monitor the capsule monitor time relative to a time threshold,
determine whether the first resistance is within a resistance range in response to the first power not exceeding the first power threshold and the capsule monitor time not exceeding the time threshold, and
cease applying the first power to the first contact point of the aerosol-generating device in response to the first resistance not being within the resistance range.

5. The capsule monitoring system of claim 4, wherein the at least one processor is configured to execute the instructions to cause the capsule monitoring system to display a fault indicator.

6. The capsule monitoring system of claim 3, wherein the at least one processor is configured to execute the instructions to cause the capsule monitoring system to,
monitor the first power relative to the first power threshold,
monitor the capsule monitor time relative to a time threshold,
determine whether the first resistance is within a resistance range in response to the first power not exceeding the first power threshold and the capsule monitor time not exceeding the time threshold, and
increase the first power applied to the first contact point of the aerosol-generating device in response to the first resistance being within the resistance range.

7. The capsule monitoring system of claim 3, wherein the at least one processor is configured to execute the instructions to cause the capsule monitoring system to,
monitor the first power relative to the first power threshold,
monitor the capsule monitor time relative to a time threshold, and
cease applying the first power to the first contact point of the aerosol-generating device in response to the first power not exceeding the first power threshold and the capsule monitor time exceeding the time threshold.

8. The capsule monitoring system of claim 7, wherein the at least one processor is configured to execute the instructions to cause the capsule monitoring system to return the aerosol-generating device to normal operation.

9. The capsule monitoring system of claim 3, wherein the at least one processor is configured to execute the instructions to cause the capsule monitoring system to,
monitor the first power relative to the first power threshold,
monitor the first resistance relative to a maximum heater resistance in response to the first resistance not being within the resistance operation range and the first power exceeding the first power threshold, and
display a fault indicator in response to the first resistance not exceeding the maximum heater resistance.

10. The capsule monitoring system of claim 3, wherein the at least one processor is configured to execute the instructions to cause the capsule monitoring system to,
monitor the first power relative to the first power threshold,
monitor the first resistance relative to a maximum heater resistance in response to the first resistance not being within the resistance operation range and the first power exceeding the first power threshold, and
return the aerosol-generating device to normal operation in response to the first resistance exceeding the maximum heater resistance.

11. The capsule monitoring system of claim 3, wherein the at least one processor is configured to execute the instructions to cause the capsule monitoring system to,
monitor the first power relative to the first power threshold, and
cease applying the first power to the first contact point in response to the first power exceeding the first power threshold.

12. The capsule monitoring system of claim 1, wherein the at least one processor is configured to execute the instructions to cause the capsule monitoring system to,
store the first resistance in the memory of the capsule monitoring system after determining the first resistance is within the resistance operation range,
detect start of a session of the aerosol-generating device,
apply a preheat power to the first contact point of the aerosol-generating device,
determine a preheat resistance between the first contact point and the second contact point,
determine whether the preheat resistance is within a resistance tolerance range, the resistance tolerance range based on the first resistance stored in the memory of the aerosol-generating device, and
return the aerosol-generating device to a preheat operation of the session in response to the preheat resistance being within the resistance tolerance range.

13. The capsule monitoring system of claim 12, wherein the at least one processor is configured to execute the instructions to cause the capsule monitoring system to increase the preheat power until the preheat power exceeds a preheat power threshold.

14. The capsule monitoring system of claim 13, wherein the at least one processor is configured to execute the instructions to cause the capsule monitoring system to,
monitor the preheat power relative to the preheat power threshold,
determine whether the preheat resistance is within a resistance range in response the preheat power not exceeding the preheat power threshold, and
cease applying the preheat power to the first contact point of the aerosol-generating device in response to the preheat resistance not being within the resistance range.

15. The capsule monitoring system of claim 14, wherein the at least one processor is configured to execute the instructions to cause the capsule monitoring system to display a fault indicator.

16. The capsule monitoring system of claim 13, wherein the at least one processor is configured to execute the instructions to cause the capsule monitoring system to,
monitor the preheat power relative to the preheat power threshold,
determine whether the preheat resistance is within a resistance range in response the preheat power not exceeding the preheat power threshold, and
increase the preheat power applied to the first contact point of the aerosol-generating device in response to the preheat resistance being within the resistance range.

17. The capsule monitoring system of claim 13, wherein the at least one processor is configured to execute the instructions to cause the capsule monitoring system to,
monitor the preheat power relative to the preheat power threshold, and
cease applying the preheat power to the first contact point of the aerosol-generating device in response to the preheat resistance not being within the resistance tolerance range and the preheat power exceeding the preheat power threshold.

18. The capsule monitoring system of claim 17, wherein the at least one processor is configured to execute the instructions to cause the capsule monitoring system to display a fault indicator.

19. The capsule monitoring system of claim 1, wherein the mechanism detection switch is configured to be actuated when a closure mechanism of the aerosol-generating device is closed.

20. The capsule monitoring system of claim 19, wherein the closure mechanism is configured to secure a capsule within the aerosol-generating device.

21. The capsule monitoring system of claim 1, wherein the at least one processor is configured to execute the instructions to cause the capsule monitoring system to initiate a preheat operation of the aerosol-generating device after at least one of determining the first resistance being within the resistance operation range or displaying the capsule accepted indicator.

22. A capsule monitoring system for an aerosol-generating device, the capsule monitoring system comprising:
at least one processor; and
a memory coupled to the at least one processor and storing instructions,
wherein the at least one processor is configured to execute the instructions to cause the capsule monitoring system to,
detect start of a session of the aerosol-generating device,
apply a preheat power to a first contact point of the aerosol-generating device,
determine a preheat resistance between the first contact point and a second contact point,
determine whether the preheat resistance is within a resistance tolerance range, the resistance tolerance range based on a first resistance stored in the memory of the aerosol-generating device, and
continue a preheat operation of the session in response to the preheat resistance being within the resistance tolerance range.
